(19) United States
(12) Patent Application Publication
(10) Pub. No.: US 2025/0212545 A1
(43) Pub. Date: Jun. 26, 2025

(54) IMAGE SENSORS AND METHODS OF MANUFACTURE

(71) Applicant: Taiwan Semiconductor Manufacturing Company, Ltd., Hsinchu (TW)

(72) Inventors: Keng-Yu Chou, Kaohsiung City (TW); Chun-Hao Chuang, Hsinchu City (TW); Shang-Fu Yeh, Hsin Chu City (TW); Wei-Chieh Chiang, Yuanlin Township (TW); Tzu-Jui Wang, Fengshan City (TW)

(21) Appl. No.: 18/395,841

(22) Filed: Dec. 26, 2023

(51) Int. Cl. H01L 27/146

(52) U.S. Cl. CPC H10F 39/811; H10F 39/011; H10F 39/182

(57) ABSTRACT

An image sensor has floating diffusion nodes and transfer gates on a first chip and source followers, dual conversion gain (DCG) transistors, select gates, and reset gates on a second chip. The floating diffusion nodes on the first chip are non-shared so that there is one for each photodetector pixel. The capacitance of the floating diffusion node proves to be lower in this two-chip non-shared arrangement than is feasible in any single chip arrangement. The DCG transistor may be placed in series with the reset transistor so that the DCG transistor may be included in the pixel circuit without adding wiring to the floating diffusion node. The wiring that is included in the floating diffusion node may be kept substantially vertical with only a single short horizontal wire that provides a connection between the source follower gate electrode and the DCG transistor source.

### BACKGROUND

Many modern day electronic devices (e.g., digital cameras, optical imaging devices, etc.) comprise image sensors. An image sensor includes an array of photosensitive areas which are operative as transducers that convert light into electrical charges. Examples of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a cross-sectional view of an image sensor according to some aspects of the present disclosure.

FIG. 2 schematically illustrates the distribution of in-pixel circuitry on the second chip of the image sensor of FIG. 1.

FIG. 3 provides a circuit diagram for an image sensor according to some embodiments.

FIGS. 4-6 illustrate plan views showing layouts for the in-pixel circuitry on the second chip in accordance with various embodiments.

FIGS. 7-11 illustrate plan views showing layouts for the transfer gate and the floating diffusion region on the first chip in accordance with various embodiments.

FIGS. 12-13 provide corresponding plan views illustrating the relationship between color filters and photodetector pixels in accordance with some embodiments.

FIG. 14 illustrates a cross-sectional view of an image sensor according to another embodiment.

FIG. 15 illustrates a cross-sectional view of an image sensor according to another embodiment.

FIGS. 16-36 illustrate a method of manufacturing an image sensor in accordance with some embodiments.

FIG. 37 is a flow chart of a process in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

One type of CMOS image sensor has an array of photodetectors each of which includes a photosensitive area within a semiconductor body, a transfer gate, a floating diffusion node, a source follower (SF), a select gate, and a reset gate. When the reset gate is closed, the floating diffusion node is charged to a reference voltage. Light is transduced into electrical charges within the photosensitive area. The charges accumulate until the transfer gate is closed allowing them to flow to the floating diffusion node. The charges alter the floating diffusion node voltage. The floating diffusion node is coupled to a gate electrode of the SF. The SF is connected in series with the select gate. When the select gate is closed, current flows through the SF and the select gate. The magnitude of that current is sensitive to the voltage applied to the SF gate electrode by the floating diffusion node. The current is detected and used to infer the amount of charge that was transferred to the floating diffusion node, which in turn reflects the amount of radiation that was incident on the photosensitive area over a sampling interval.

It has long been appreciated that the floating diffusion node and all the transistors on the drain side of the transfer gate may be shared among adjacent photodetectors. In fact, as photodetector pixels have become smaller, such transistor sharing has becomes standard. Without such sharing, there would not be enough room around the photodetectors in a small pixel device (e.g., less than about 2 μm) to accommodate all the transistors.

Conversion gain is a significant parameter in a CMOS image sensor of the type just described. The conversion gain is related to the capacitance of the floating diffusion node. If the capacitance is too low (conversion gain too high) for a given sampling rate, the photodetectors will experience saturation so that variations in light intensity at the high end will be lost. If the capacitance is too high (conversion gain too low), there will be excessive noise in the voltage signal and variations in light intensity at the low end will be lost. The capacitance of the floating diffusion node includes contributions from a floating diffusion region, which is the drain region of the transfer gate, the source region of the reset gate, the gate electrode of the SF, and the wiring that connects these structures. If the floating diffusion node is shared among a plurality of pixels, the capacitance includes contributions from the drain regions of each of the associated transfer gates.

There has long been an interest in connecting an additional transistor to the floating diffusion node to widen the range of lighting conditions over which the image sensor can be effective. The additional transistor, which is called a dual conversion gain (DCG) transistor, allows the photodetector to be switched between a low conversion gain mode and a high conversion gain mode. In the low conversion gain mode, the DCG transistor is closed so that additional capacitance is added to the floating diffusion node. In the high conversion gain mode, the DCG transistor is open so that the additional capacitance is removed from the floating diffusion node.

Some aspects of the present disclosure relate to an image sensor with a structure that provides an exceptionally high conversion gain and low noise in the high conversion gain mode. The structure provides a separate floating diffusion node for each photodetector pixel and places the SF, the dual conversion gain transistor, the select gate, and the reset gate on a second chip. The inventors have found that the capacitance of the floating diffusion node can be kept lower in this two-chip non-shared arrangement than is feasible in any single chip arrangement. In some embodiments, the DCG transistor is placed in series with the reset transistor so that the DCG transistor may be added to the circuit without increasing the amount of wiring that contributes capacitance of the floating diffusion node. In these embodiments, the floating diffusion node includes the source region of the DCG transistor but does not include the source region of the reset transistor unless the DCG transistor is closed. When the DCG transistor is open, the wiring in the floating diffusion node may be substantially vertical with only a single short horizontal wire that provides a connection between the SF gate electrode and the DCG transistor source.

The wiring that is part of the floating diffusion node extends through a first metal interconnect structure formed on the first chip and a second metal interconnect structure formed on the second chip. In some embodiments, the wiring is confined within an area that is vertically aligned with the corresponding photodetector cell. In some embodiments, the wiring structure has only a single branch. In some embodiments, that single branch is a horizontal wire that abuts two contact plugs on the second chip. In some embodiments, the horizontal wire is directly opposite the corresponding floating diffusion region, which is on the first chip. In some embodiments, the wiring structure forms a straight vertical column between the horizontal wire and the floating diffusion region.

In some embodiments, the wiring structure comprises a wire that extends laterally from directly over a first contact plug that connects to the SF gate electrode to directly over a second contact plug that connects to the source region of the DCG transistor. The SF and the DCG transistor are arranged so as to keep this wire short. In some embodiments, the SF gate electrode and the source region of the DCG transistor are separated only by an isolation structure. In some embodiments, the SF and the DCG transistor are at right angles. In some embodiments, the DCG transistor is aligned with the SF gate electrode along a drain to source direction. In some embodiments, the SF and the DCG transistor have parallel orientations. In some embodiments, the SF and the DCG transistor are offset in the parallel orientation so that the SF gate electrode is directly across from the source region of the DCG transistor.

In some embodiments, the image sensor includes a third semiconductor substrate. The third semiconductor substrate may be in a stacked arrangement with the first semiconductor substrate and the second semiconductor substrate. The third semiconductor substrate may contain an application specific integrated circuit (ASIC). The ASIC uses data from the photodetector array and may contain components such as memory cells, logic circuits, and the like. Placing this additional circuitry on the third chip preserves the image sensing area on the first chip and leaves more area for in-pixel circuitry on the second chip.

The first semiconductor substrate includes an isolation structure in the form of a grid having segments that provide isolation between the photosensitive areas of adjacent photodetectors. The grid has cells. Each photosensitive area is in a corresponding cell and the cells may be referred to as photodetector pixels. In some embodiments, the floating diffusion regions are within the boundaries of the cells, wherein the boundaries correspond to segments of the isolation structure that surround the cell.

A floating diffusion region may have any suitable location with the cell. The transfer gate is positioned so that it may selectively couple the floating diffusion region to a region where charges produced in the photosensitive area accumulate. In some embodiments, the photosensitive area comprises a photodiode. In some embodiments, the transfer gate is a vertical transfer gate. The floating diffusion region is kept small. In some embodiments, the source side of the transfer gate is wider than the floating diffusion region side of the transfer gate. This facilitates transferring charges from the photodiode while keeping the floating diffusion region small. In some embodiments, the floating diffusion region is in a corner of the photodetector cell. In some embodiments, the floating diffusion region has a width no more than about twice the width of a contact plug that connects the wiring structure to the floating diffusion region. This keeps the floating diffusion region small while still allowing it to be large enough to consistently land the contact plug.

In some embodiments, four adjacent photodetector pixels are grouped together under a microlens and associated color filter. The grouping may be of the type found in image sensors commonly referred to as Quad Bayer filters. In an ordinary Quad Bayer filter, the four adjacent photodetector pixels share a floating diffusion node. When lighting levels are high, the Quad Bayer filter may be operated in a high resolution mode wherein the four photodetector pixels transfer their charges to the floating diffusion node one at a time, with reset operations between the transfers. When lighting levels are lower, the Quad Bayer filter may be operated in a high sensitivity mode wherein charges are transferred to the floating diffusion node from all four of the four photodetector pixels between reset operations. An image sensor according to the present disclosure has been determined to perform better for both conditions. The lower floating diffusion node capacitance allows the high resolution mode to be carried to lower lighting levels. At the lower lighting levels, the outputs of the four photodetector pixels may be digitally combined to provide an output with lower noise level than is achieved when there are four separate charge transfers to one floating diffusion node.

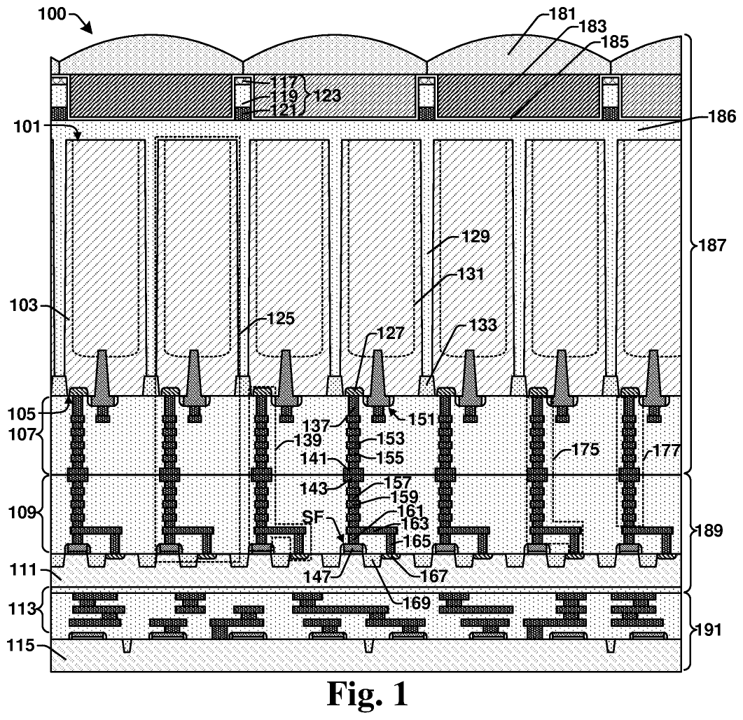

FIG. 1 illustrates a cross-sectional view of an image sensor 100 according to some embodiments. The image sensor 100 is an integrated circuit (IC) device and may be 3D-IC including a first chip 187, a second chip 189, and a third chip 191 stacked, bonded, and interconnected together. The first chip 187 includes a semiconductor body 103 and a first metal interconnect structure 107. The second chip 189 includes a second semiconductor substrate 111 and a second metal interconnect structure 109. The third chip 191 includes a third semiconductor substrate 115 and a third metal interconnect structure 113.

An array of photodiodes 131 is disposed within the semiconductor body 103. A deep trench isolation (DTI) structure 129 provides isolation between photodiodes 131 that are adjacent within the array. The photodiodes 131 are photosensitive structures. The DTI structure 129 is in the form of a grid having segments between adjacent photodiodes 131. One of the photodiodes 131 is within each cell of the grid, and each cell of the grid corresponds to a photodetector pixel 125.

Each photodetector pixel 125 includes a photodiode 131, a transfer gate 151, and a floating diffusion region 127. A wiring structure 175 couples the floating diffusion region 127 on the first chip 187 to additional in pixel circuitry on the second chip 189. More specifically, each wiring structure 175 couples one of the floating diffusion regions 127 to a gate electrode 147 of a source follower SF and a source region 167 on the second chip 189.

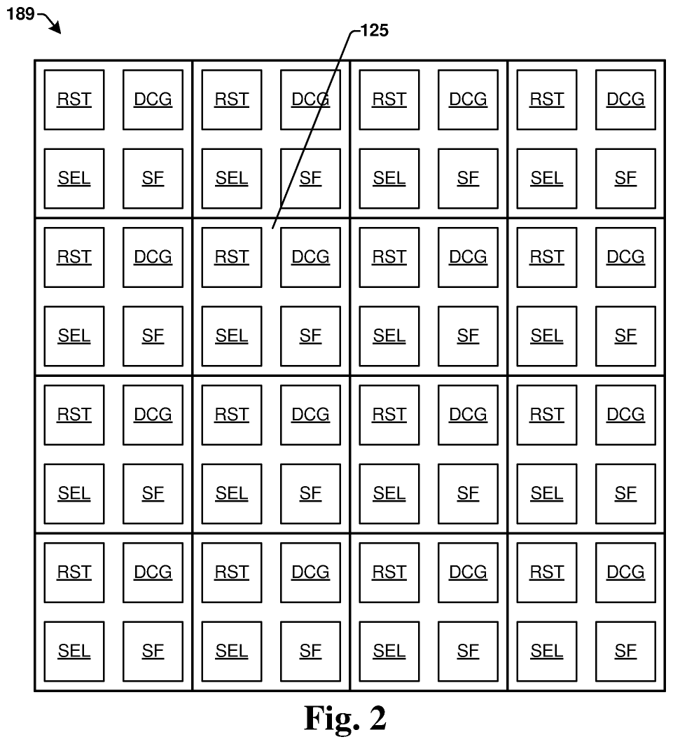

FIG. 2 provides a plan view of the second chip 189 schematically illustrating additional circuitry of the photodetector pixels 125. As illustrated by FIG. 2, each photodetector pixel 125 comprises a source follower SF, a dual conversion gain transistor DCG, a reset transistor RST, and a select gate SEL on the second chip 189. Of these transistors, only the source follower SF and the source region 167 of the dual conversion gain transistor DCG are shown in FIG. 1.

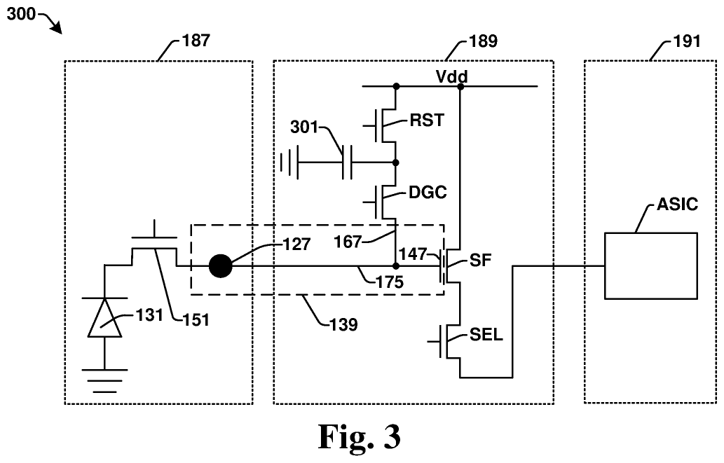

FIG. 3 provides a circuit diagram 300 that illustrates how the components of a photodetector pixel 125 are distributed between the first chip 187 and the second chip 189, how they are interconnected, and how they are coupled to an application specific integrated circuit ASIC on the third chip 191. As shown in FIG. 3, the floating diffusion region 127, the wiring structure 175, the gate electrode 147 of the source follower SF, and the source region 167 of the dual conversion gain transistor DCG are all included in a floating diffusion node 139. If the dual conversion gain transistor DCG is closed, the floating diffusion node 139 will further include the capacitance 301.

The dual conversion gain transistor DCG and the reset transistor RST are connected in series between the floating diffusion node and a supply voltage Vdd. Closing the dual conversion gain transistor DCG and the reset transistor RST resets the floating diffusion node 139 to the supply voltage Vdd. Closing the transfer gate 151 transfers charge carriers, e.g. electrons, from the photodiode 131 to the floating diffusion node 139, altering its voltage. If the select gate SEL is closed, a current will flow from Vdd to the ASIC through the source follower SF and the select gate SEL. The magnitude of that current will vary in proportion to a difference between the threshold voltage of the source follower SF and the voltage of the floating diffusion node 139.

An example of the wiring structure 175 is illustrated by FIG. 1. As shown in FIG. 1, the wiring structure 175 includes a contact plug 161 abutting the gate electrode 147 of the source follower SF, a contact plug 165 abutting the source region 167, a wire 163 that connects the contact plug 161 and the contact plug 165, and the wiring 177 that connects the wire 163 to the floating diffusion region 127. The wiring 177 includes a contact plug 137 abutting the floating diffusion region 127, wires 153 and vias 155 in the first metal interconnect structure 107, wires 159 and vias 157 in the second metal interconnect structure 109, and contact pads 141 and 143 on the first chip 187 and the second chip 189 respectively. The wires 153 and 159 within the wiring 177 are illustrated as being wider than the respective vias 155 and 157, but may be made short and narrow up to the constraints imposed by design rules.

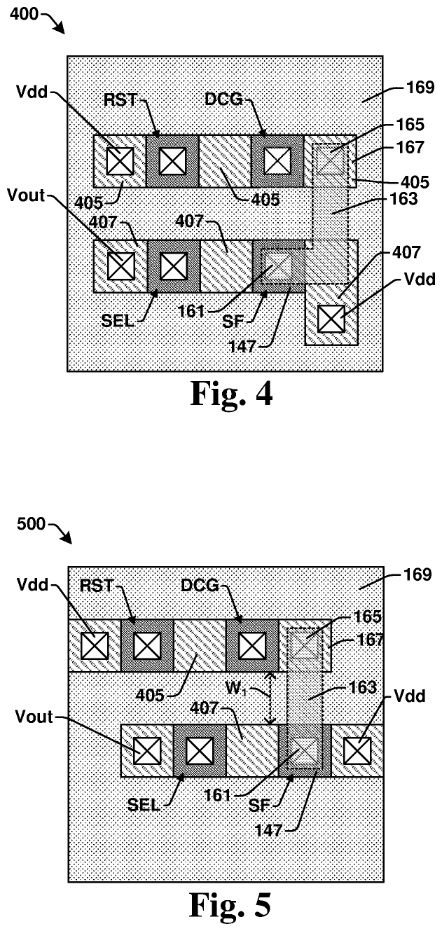

FIG. 4 provides a plan view 400 illustrating a possible layout on the second chip 189 of the in pixel transistors corresponding to one of the photodetector pixels 125 (see FIG. 2). A shallow trench isolation (STI) structure 169 surrounds and delineates a first active device area 405 and a second active device area 407. The reset transistor RST and the dual conversion gain transistor DCG are in the first active device area 405. The select gate SEL and the source follower SF are in the second active device area 407. The wire 163 connects a contact plug 165 for the source region 167 of the dual conversion gain transistor DCG to a contact plug 161 for the gate electrode 147 of the source follower SF. The wire 163 may be in any metallization layer of the second metal interconnect structure 109, but in some embodiments the wire 163 is in a lowest metallization layer so that it makes direct contact with the contact plugs 161 and 165. Placing the wire 163 lower in the second metal interconnect structure 109 reduces the length of vertical connections in the wiring structure 175 (see FIG. 1).

FIG. 5 provides a plan view 500 illustrating another possible layout on the second chip 189 of the in pixel transistors corresponding to one of the photodetector pixels 125 (see FIG. 2). The layout of the plan view 500 allows the wire 163 to be shorter than in the layout of the plan view 400 of FIG. 4, which reduces the capacitance of the floating diffusion node 139 (see FIG. 3). In the plan view 500, the dual conversion gain transistor DCG and the source follower SF are arranged in parallel (in terms of source to drain directions) and are offset from one another so that the source region 167 is directly across from the gate electrode 147. The source region 167 and the gate electrode 147 are separated by a width W1, which is the width of a portion of the isolation structure 169 that is between the dual conversion gain transistor DCG and the source follower SF. In some embodiments, the isolation structure 169 is a shallow trench isolation structure and the width W1 is the narrowest width of any shallow trench isolation structure that is on the second chip 189.

FIG. 6 provides a plan view 600 illustrating another possible layout on the second chip 189 of the in pixel transistors corresponding to one of the photodetector pixels 125 (see FIG. 2). The layout of the plan view 600 also allows the wire 163 to be shorter than in the layout of the plan view 400 of FIG. 4. In the plan view 600, the dual conversion gain transistor DCG and the source follower SF are arranged so as to be perpendicular (in terms of source to drain directions) and are positioned so that the source region 167 is directly across from the gate electrode 147. As in the plan view 500 of FIG. 5, the source region 167 and the gate electrode 147 are separated by only a width W1 of a portion of the isolation structure 169 that separates the dual conversion gain transistor DCG and the source follower SF. Optionally, the Vdd connections could be shared between adjacent photodetector pixels 125 (see FIG. 2) so as to make the layout more area efficient.

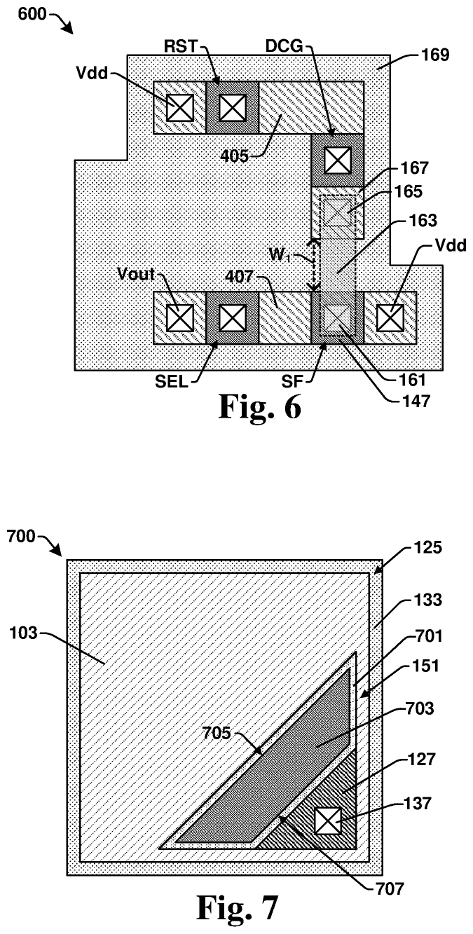

FIG. 7 provides a plan view 700 illustrating a possible layout for one of the photodetector pixels 125 on the first chip 187 (see FIG. 1). As shown by the plan view 700, the photodetector pixel 125 is surrounded by segments of a shallow trench isolation structure 133, which extends the DTI structure 129 to the front side 105 (see FIG. 1). The transfer gate 151 includes a gate electrode 703 surrounded by a spacer 701. The gate electrode 703 has a drain side 707 and a source side 705. The source side 705 is wider than the drain side 707. The floating diffusion region 127 is in a corner of the photodetector pixel 125, is on the drain side 707 of the gate electrode 703, and provides a drain region for the transfer gate 151. The source region of the transfer gate 151 is not shown and may be beneath the surface of the semiconductor body 103. In some embodiments, the transfer gate 151 is a vertical transfer gate. A vertical transfer gate has a gate electrode extending below the surface of the semiconductor body 103 so as form a channel to an area of the photodiode 131 where charges accumulate (see FIG. 1).

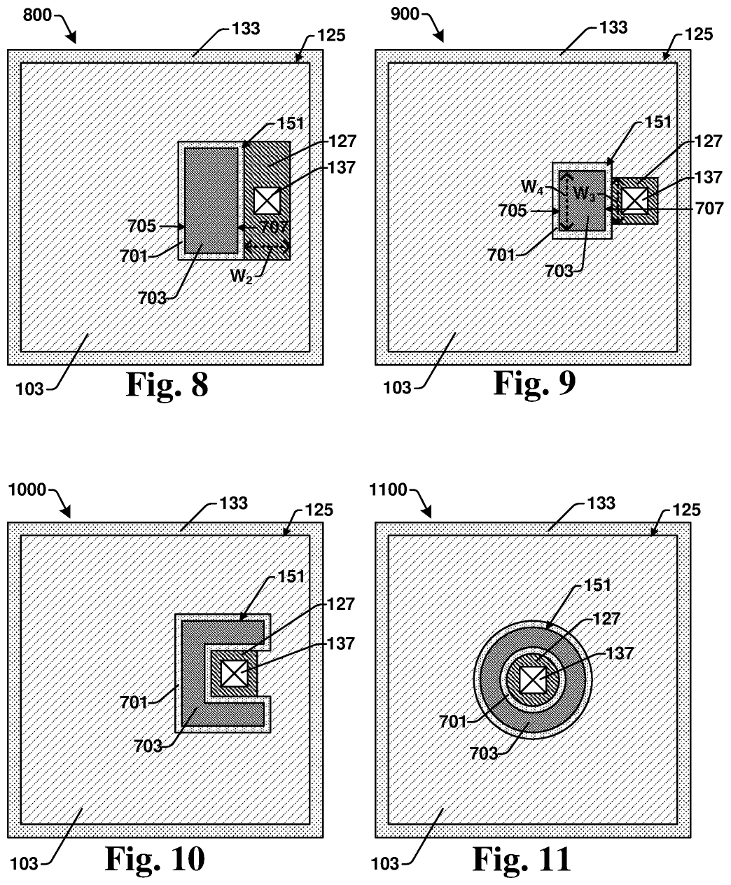

FIG. 8 provides a plan view 800 illustrating another possible layout for one of the photodetector pixels 125 on the first chip 187 (see FIG. 1). As shown by the plan view 800 the transfer gate 151 may have a conventional rectangular shape. With reference to FIG. 1, the portion of the photodetector pixel 125 on the first chip 187 may be directly opposite the portion of the photodetector pixel 125 on the second chip 189. In some embodiments, the portion of the photodetector pixel 125 on the first chip 187 is slightly offset from the portion of the photodetector pixel 125 on the second chip 189, but the chips are aligned so that the floating diffusion region 127 is directly opposite the corresponding wire 163 on the second chip 189. This allows the wiring 177 that connects the floating diffusion region 127 to the wire 163 to be a straight vertical column of metal with no lateral branches. The width W2 of the floating diffusion region 127 may be kept small so as to reduce the area and capacitance of the floating diffusion region 127. In some embodiments, the width W2 is about twice a width of the contact plug 137 or less.

FIG. 9 provides a plan view 900 illustrating another possible layout for one of the photodetector pixels 125. As shown by the plan view 900 the floating diffusion region 127 may have a width W3 that is less than a width W4 of the gate electrode 703. This structure also facilitates reducing the area of the floating diffusion region 127. In some embodiments, the width W3 is about twice a width of the contact plug 137 or less. In some embodiments, the width W3 is about equal to the width W2 (see FIG. 8).

FIG. 10 provides a plan view 1000 illustrating another possible layout for one of the photodetector pixels 125. As shown by the plan view 1000, the gate electrode 703 may be shaped so as to partially wrap around the floating diffusion region 127. This structure facilitates reducing the size of the floating diffusion region 127 while maintaining efficient charge transfer between the photodiode 131 and the floating diffusion region 127.

FIG. 11 provides a plan view 1100 illustrating another possible layout for one of the photodetector pixels 125. As shown by the plan view 1100, the gate electrode 703 may be shaped so as to wrap completely around the floating diffusion region 127. This structure may allow a still further reduction in the size of the floating diffusion region 127.

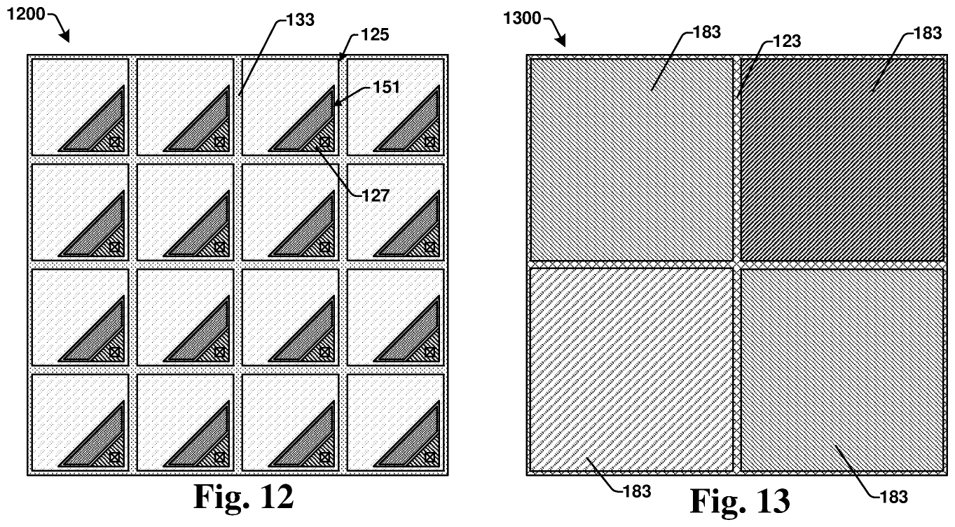

FIG. 12 provides a plan view 1200 illustrating a 4×4 group of photodetector pixels 125 on the front side of the first chip 187. FIG. 13 provides a plan view 1300 illustrating a corresponding area on the back side 101 of the first chip 187 (see FIG. 1). As shown by the plan views 1200 and 1300, there is a 2×2 grid of photodetector pixels 125 under each color filter 183. The color filters 183 may be in a Bayer pattern, or some other suitable pattern. In some embodiments, two of the photodetector pixels 125 in each 2×2 grouping under a color filter 183 are used for contrast detection autofocus. Under low light conditions, contrast detection autofocus works better than phase detection autofocus. When used with the structure of the present disclosure, contrast detection autofocus is operative at even lower light conditions.

Returning to FIG. 1, microlenses 181 are disposed over the color filters 183 on the back side 101 of the semiconductor body 103. In the image sensor 100, each of the microlenses 181 has a footprint that corresponds to one color filter 183 and four of the photodiodes 131 in a 2×2 grid arrangement. The microlenses 181 are configured to focus incident radiation on photosensitive areas of corresponding photodiodes 131. In an alternative embodiment, each of the microlenses 181 corresponds to only one photodiode 131.

A composite grid 123 over the back side 101 includes segments disposed between and separating adjacent color filters 183. The composite grid 123 may include a metal layer 121, a dielectric layer 119, and a hard mask layer 117. The metal layer 121 provides a back side metal grid. An encapsulation layer 185 may be disposed over and along the sidewalls of the composite grid 123. A dielectric 186 may separate the composite grid 123 and the color filter 183 from the back side 101. The metal layer 121 may be grounded to the semiconductor body 103. This grounding may be provided by ground bars (not shown) disposed in a peripheral area (not shown) of the semiconductor body 103, which is outside the image sensing area.

As noted, some of the photodetector pixels 125 may be image sensing pixels and others PDAF pixels. In some embodiments where there are four photodetector pixels in a 2×2 array under each microlens 181 or color filter 183, two diagonally opposite photodetector pixels 125 are PDAF pixels. Differences between image sensing pixels and PDAF pixels may be found in the application specific integrated circuit ASIC. In particular, there may be differences in the amplification circuitry connected to these different types of pixels.

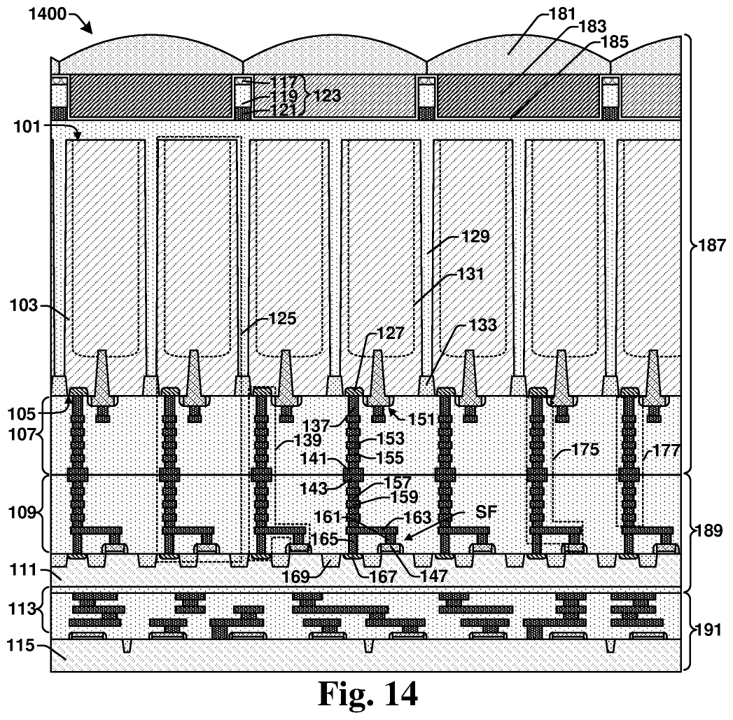

FIG. 14 illustrates a cross-sectional view of an image sensor 1400 according to some other embodiments. The image sensor 1400 of FIG. 14 is like the image sensor 100 of FIG. 1 except that in the image sensor 100 the wiring 177 is directly opposite the gate electrode 147 of the source follower SF whereas in the image sensor 1400 of FIG. 14, the wiring 177 is directly opposite the source region 167. Either of these configurations allows laterally extending wires to be excluded from the floating diffusion node 139 with the exception of the wire 163 that extends between the contact plug 161 and the contact plug 165.

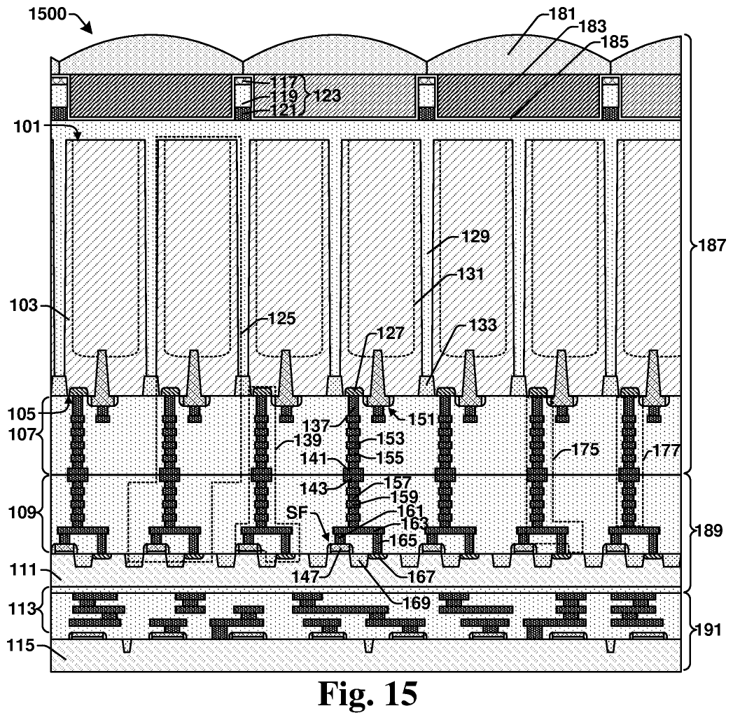

FIG. 15 illustrates a cross-sectional view of an image sensor 1500 according to some other embodiments. In the image sensor 1500, the wiring 177 is not directly opposite either the gate electrode 147 or the source region 167, but lands on the wire 163 at an intermediate location. It will be appreciated that the images sensor 100 of FIG. 1, the image sensor 1400 of FIG. 14, and the image sensor 1500 of FIG. 15 provide equal opportunities to minimize the capacitance of the wiring structure 175 in the floating diffusion node 139.

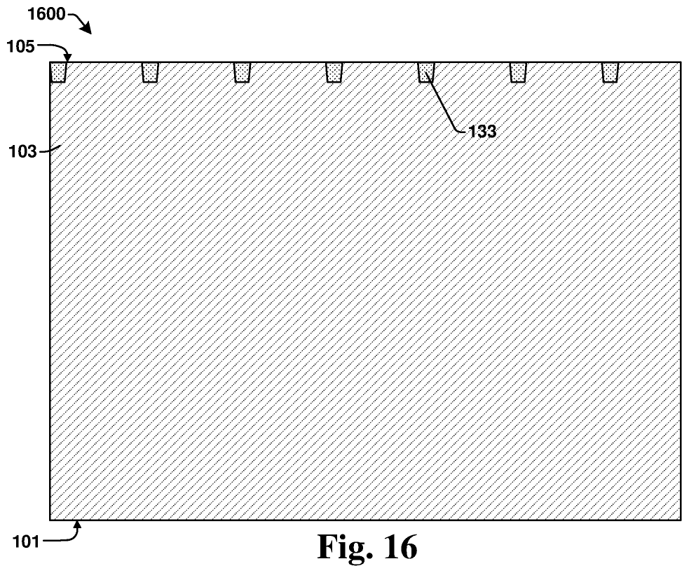

FIGS. 16-36 provide a series of cross-sectional views 1600-3600 that illustrate an image sensing integrated circuit device according to the present disclosure at various stages of manufacture according to a process of the present disclosure. Although FIGS. 16-36 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 16-36 are described in relation to a series of acts, it will be appreciated that the structures shown in FIGS. 16-36 are not limited to a method of manufacture but rather may stand alone as structures separate from the method.

As illustrated by the cross-sectional view 1600 of FIG. 16, the method may begin with forming shallow trench isolation (STI) structures 133 in the semiconductor body 103. The semiconductor body 103 may be cut from a single crystal and may be any type of semiconductor. The semiconductor may be, for example, silicon (Si), a group III-V semiconductor or some other binary semiconductor, a tertiary semiconductor (e.g., AlGaAs), a higher order semiconductor, or the like. In some embodiments, the semiconductor body 103 is or comprises silicon (Si) or the like. Forming the STI structures 133 may include forming a mask and etching trenches in the front side 105, stripping the mask, depositing a dielectric so as to fill the trenches, and planarizing. The dielectric may be silicon dioxide (SiO₂), the like, or any other suitable dielectric.

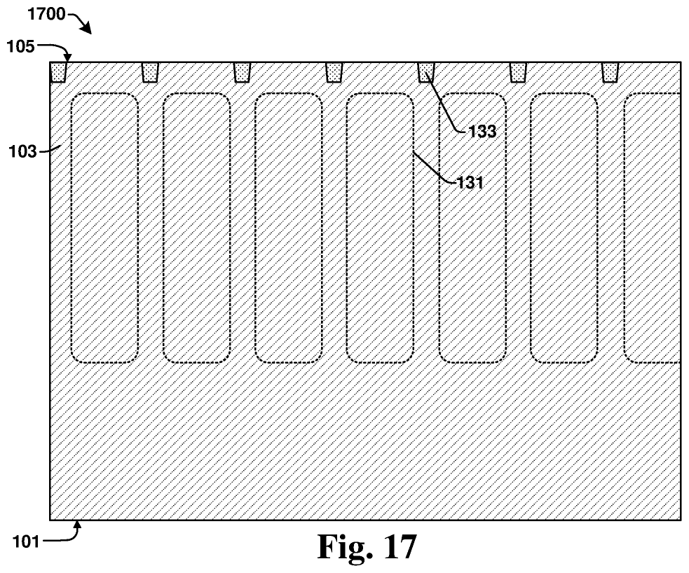

As illustrated by the cross-sectional view 1700 of FIG. 17, the method may continue with implanting dopants through the front side 105 to form the photodiodes 131. The dopants may be implanted in a series of steps that include, for example, a deep n-well implant, a shallow p-well implant, and the like. Some of these dopant implants may be carried out with masks and others without. Some of these dopant implants may be carried out before the STI structures 133 are formed.

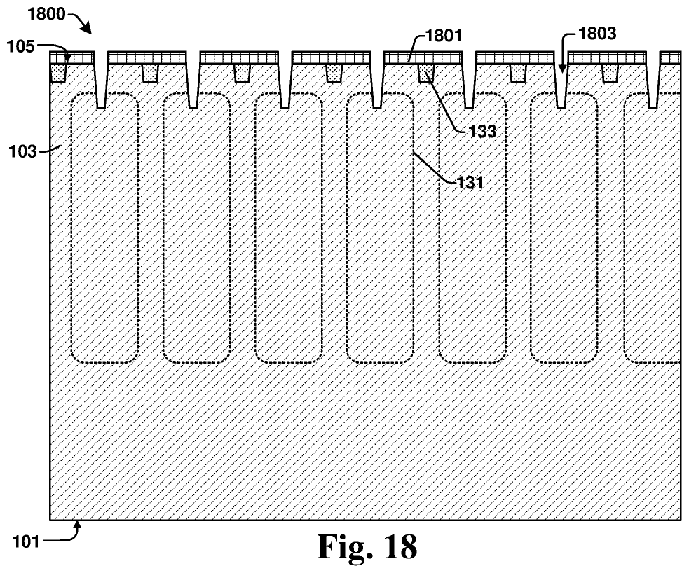

As illustrated by the cross-sectional view 1800 of FIG. 18, a mask 1801 may be formed and used to etch trenches 1803. The mask 1801, and other masks used throughout this process, may be patterned by photolithography, e-beam lithography, the like, or any other suitable method. The mask may include a photoresist mask and/or a hard mask. A hard mask may be patterned from a photoresist mask. After etching, the mask 1801 may be stripped. The trenches 1803 are for forming vertical transfer gates. If vertical transfer gates are not desired this step may be omitted.

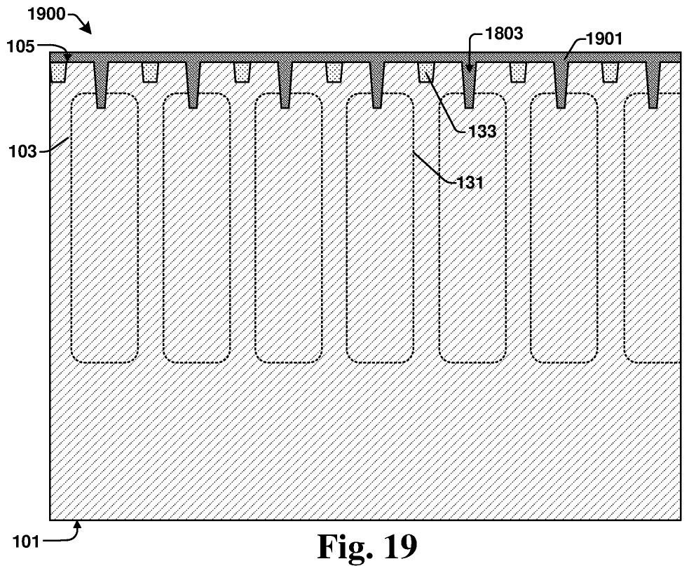

As illustrated by the cross-sectional view 1900 of FIG. 19, a gate stack 1901 may be formed. The gate stack 901 fills the trenches 1803. The gate stack 1901 may include a gate dielectric layer (not shown separately) and a gate electrode layer. The gate dielectric layer may be an oxide, the like, or some other material suitable for a gate dielectric layer. The gate electrode layer may be polysilicon, the like, or some other suitable material. These layers may be deposited by physical vapor deposition (PVD), chemical vapor deposition (CVD), atomic layer deposition (ALD), the like, or any other suitable process. The gate dielectric layer may alternatively be formed by oxidation. Optionally, the gate stack 1901 is planarized. The planarization process may be chemical mechanical polishing (CMP) or the like.

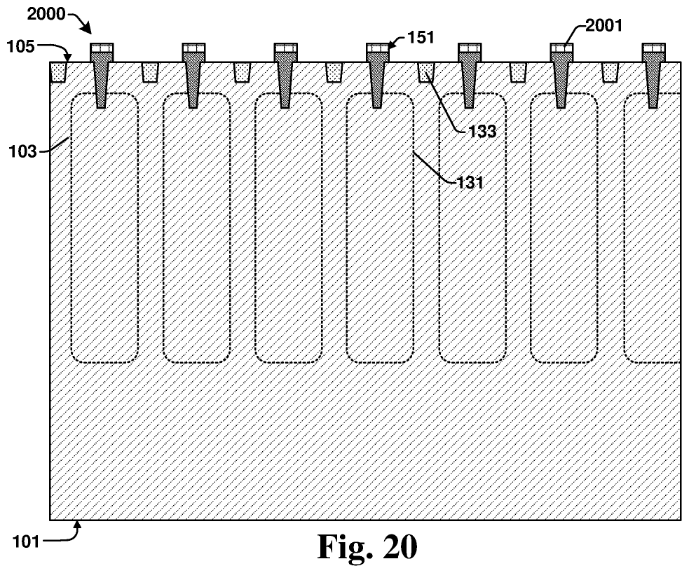

As shown by the cross-sectional view 2000 of FIG. 20, a mask 2001 may be formed and used to pattern the transfer gates 151 and/or other gates from the gate stack 1901. After patterning, the mask 2001 may be stripped.

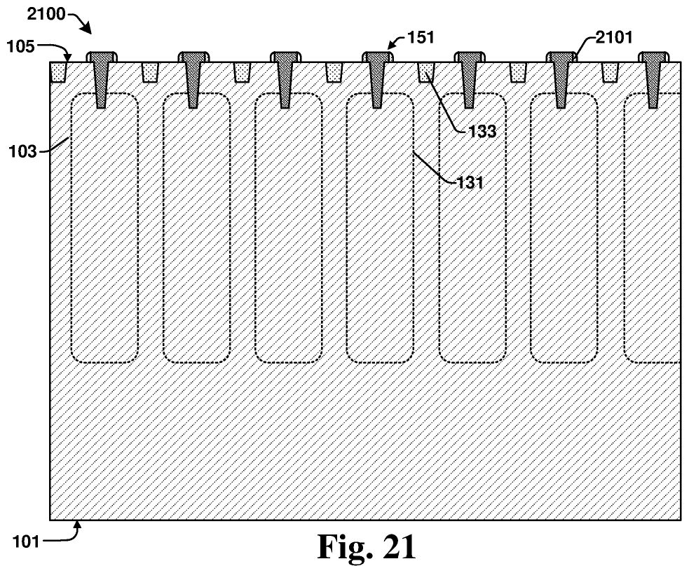

As shown by the cross-sectional view 2100 of FIG. 21, spacers 2101 may be formed around the transfer gates 151. The spacers 2101 may be formed by depositing a spacer material followed by anisotropic etching. The spacer material may include one or more layers of any suitable dielectrics. The spacer material may be or comprise, for example, silicon nitride (SiN), silicon oxynitride (SiON), silicon dioxide (SiO₂), a high-K dielectric, or the like. The spacer material may be deposited by ALD, CVD, PVD, the like, or any other suitable process.

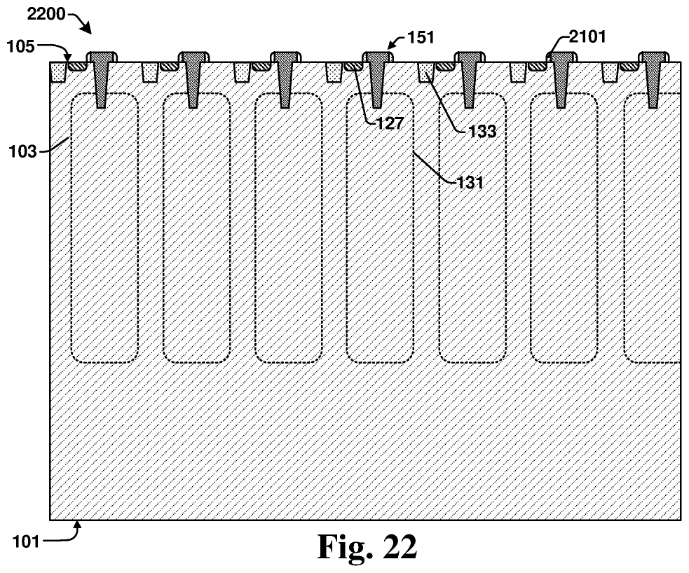

As shown by the cross-sectional view 2200 of FIG. 22, dopants may be implanted to form floating diffusion regions 127. A mask (not shown) is optionally formed prior to implanting the dopants. This dopant implantation process may form other structures such as source/drain regions for other transistors (not shown). The floating diffusion regions 127 may be aligned to the spacers 2101. The floating diffusion regions 127 may be spaced apart from the STI structures 133 to reduce leakage currents.

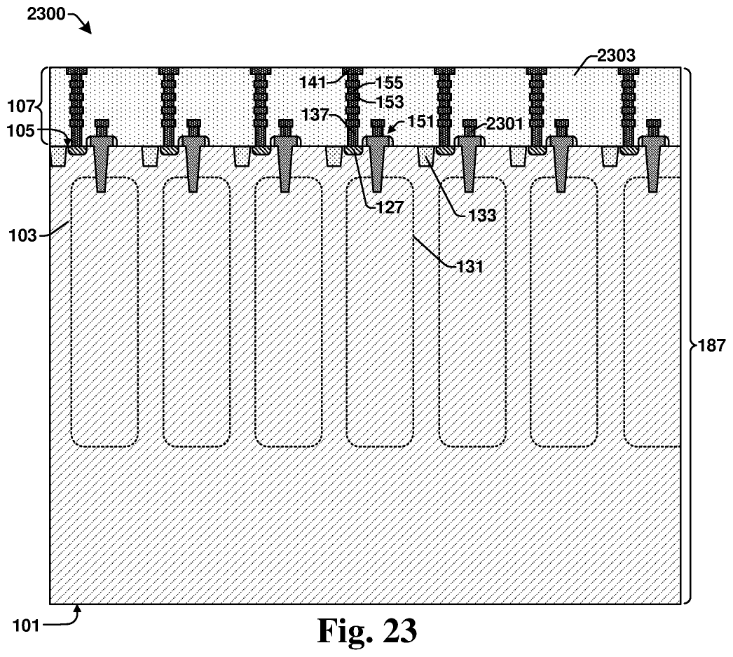

As shown by the cross-sectional view 2300 of FIG. 23, the process may continue with formation of the first metal interconnect structure 107 over the front side 105. The first metal interconnect structure 107 includes a plurality of metallization layers, each of which may be formed using a damascene or dual damascene process. The first metal interconnect structure 107 includes the contact plugs 137, the contact plugs 2301, the wires 153, the vias 155, and interlevel dielectric 2303. The wires 153 and the vias 155 may be or comprise copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. The wires 153 and the vias 155 may also include a diffusion barrier layer such as titanium (Ti), tantalum (Ta), titanium nitride (TiN), tantalum nitride (TaN), or the like. The first metal interconnect structure 107 may further include contact pads 141. The contact pads 141 may have one of the foregoing compositions or a different composition. Likewise, the contact plugs 137 and 2301 may have one of the foregoing compositions or a different composition. In some embodiments, the contact plugs 137 and 2301 have a different composition from the wires 153 and the vias 155. In some embodiments, the contact plugs 137 and 2301 comprises tungsten (W), cobalt (Co), cobalt silicide (CoSi2), nickel (Ni), nickel silicide (NiSi), an alloy thereof, or the like.

The conductive materials in the first metal interconnect structure 107 may be deposited by electroplating, electroless plating, ALD, CVD, PVD, the like, or any other suitable processes. The interlevel dielectric 2303 may include one or more layers of silicon dioxide (SiO₂), a low-κ dielectric, or an extremely low-κ dielectric. A low-κ dielectric is one having a smaller dielectric constant than silicon dioxide (SiO₂). Silicon dioxide has a dielectric constant of about 3.9. Examples of low-κ dielectrics include organosilicate glasses (OSG) such as carbon-doped silicon dioxide, fluorine-doped silicon dioxide (otherwise referred to as fluorinated silica glass (FSG), organic polymer low low-κ dielectrics, and porous silicate glass. An extremely low-κ dielectric is a material having a dielectric constant of about 2.1 or less. An extremely low-κ dielectric material is generally a low-κ dielectric material with a porous structure. Porosity reduces the effective dielectric constant. The interlevel dielectric 2303 may be deposited by ALD, CVD, PVD, the like, or any other suitable processes. The semiconductor body 103 and the first metal interconnect structure 107 comprise the first chip 187.

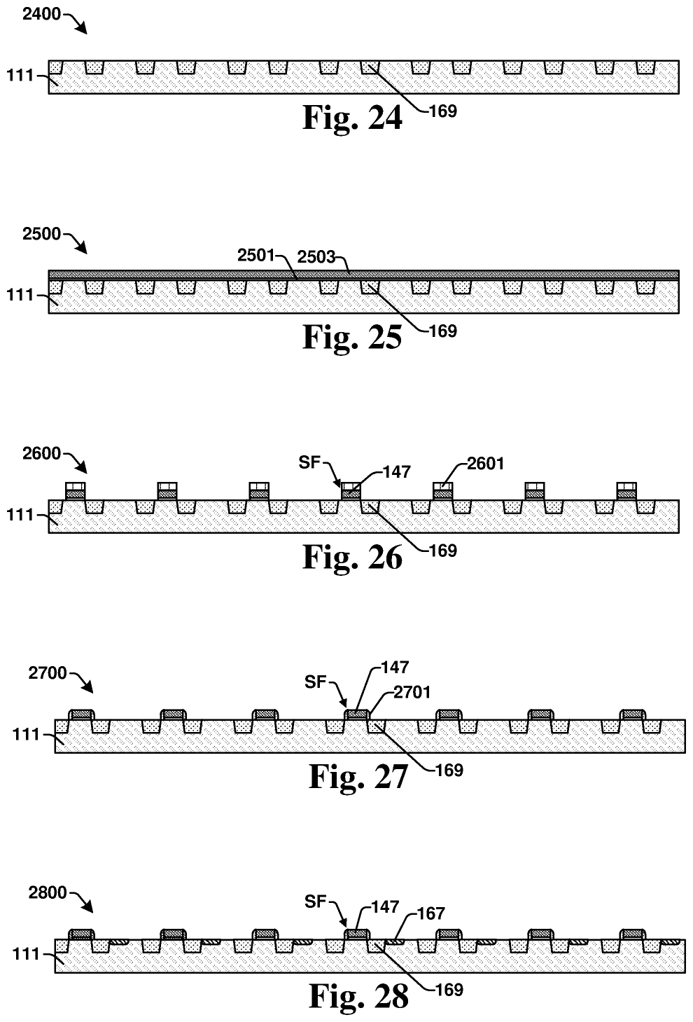

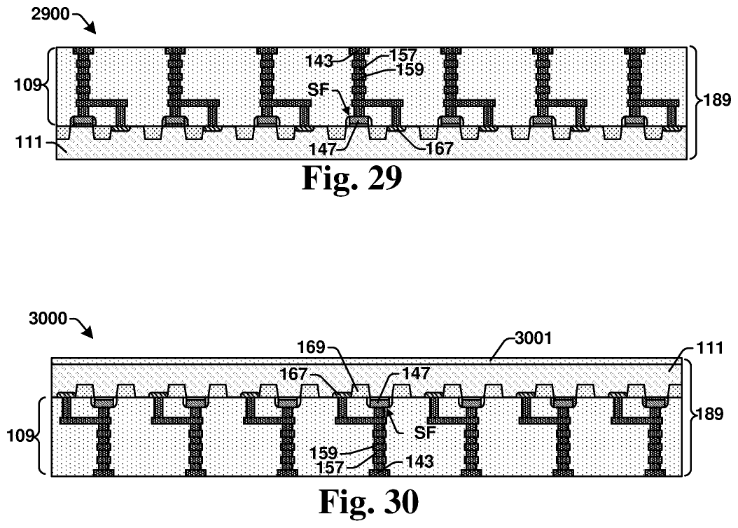

The cross-sectional views 2400 to 2900 of FIGS. 24 to 29 illustrate processing applied in making the second chip 189 (see FIG. 1). As shown by the cross-sectional view 2400 of FIG. 24, the processing may begin with forming STI structures 169 in the second semiconductor substrate 111. As shown by the cross-sectional view 2500 of FIG. 25, a gate stack including a dielectric layer 2501 and a gate electrode layer 2503. The gate stack may be patterned to define the source follower SF and other transistors as shown by the cross-sectional view 2600 of FIG. 26. As shown by the cross-sectional view 2700 of FIG. 27, sidewall spacers 2701 may be formed around the gates. After formation of the sidewall spacer 2701, a gate replacement process (not shown) could be performed to provide metal gate electrodes with high-κ dielectric layers. As shown by the cross-sectional view 2800 of FIG. 28, doping may be performed to provide the source regions 167 and other source/drain regions. As shown by the cross-sectional view 2900 of FIG. 29, the second metal interconnect structure 109 may then be formed using processes and materials such as those used for the first metal interconnect structure 107.

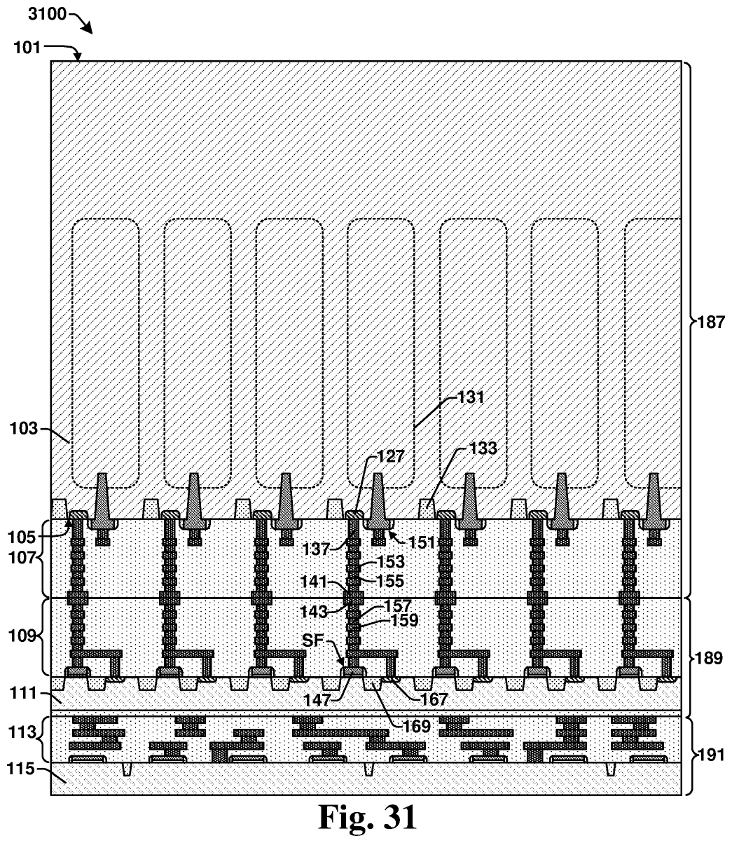

As shown by the cross-sectional view 3000 of FIG. 30, a redistribution layer 3001 or other contact structure may be formed on the back side of the second chip 189 so as to provide connections with the third chip 191 (see FIG. 1). Through substrate vias (not shown) may be formed to make connections between the redistribution layer 3001 and the second metal interconnect structure 109 on the opposite side of the second semiconductor substrate 111. If the second semiconductor substrate 111 is thinned prior to forming through substrate vias, the second chip 189 may be bonded to the first chip 187 (see FIG. 1) prior to such thinning.

As shown by the cross-sectional view 3100 of FIG. 31, the first chip 187 may be inverted and bonded to the second chip 189, which may itself be bonded to a third chip 191. The bonding between these chips may take place in any suitable order. The third chip 191 includes a third semiconductor substrate 115 and a third metal interconnect structure 113. The third chip 191 is optional in that the application specific integrated circuit ASIC (see FIG. 3) could be located in a peripheral area (not shown) of the second chip 189. The bonding processes may be oxide-to-oxide bonding, metallic bonding, combinations thereof, the like, or any other suitable bonding processes.

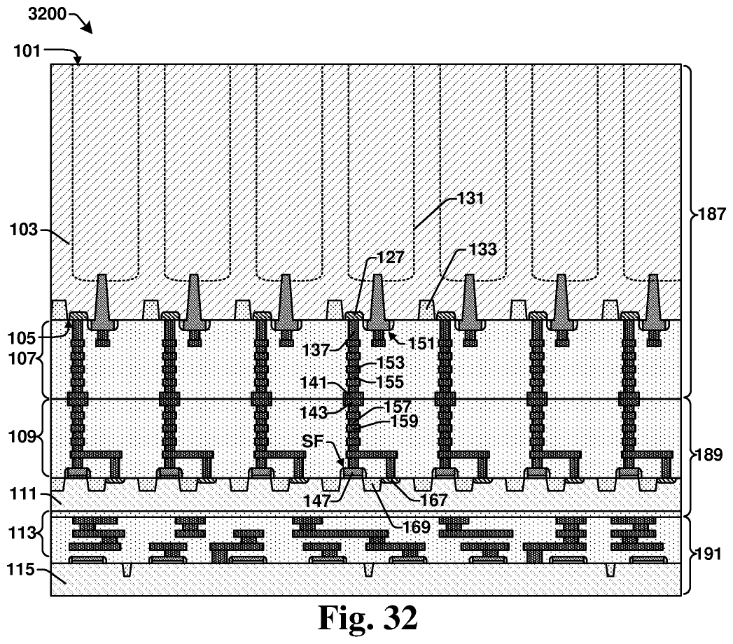

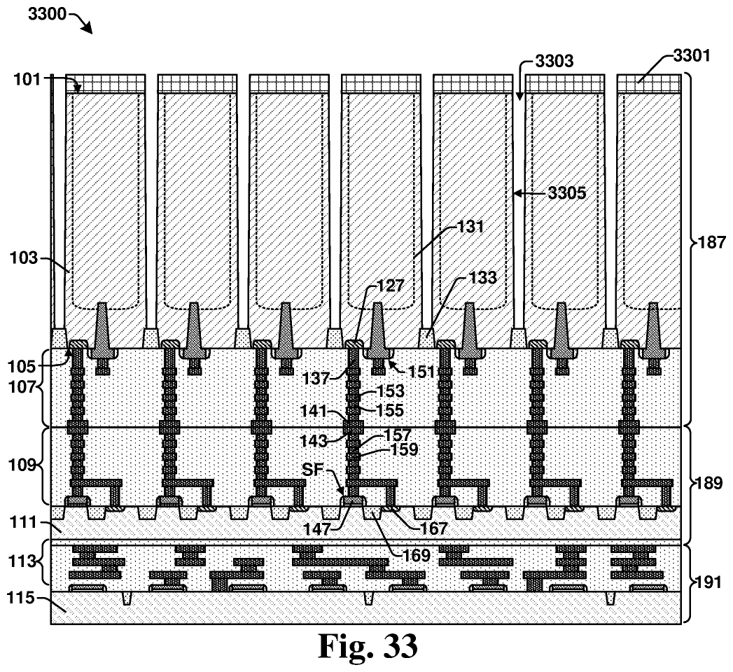

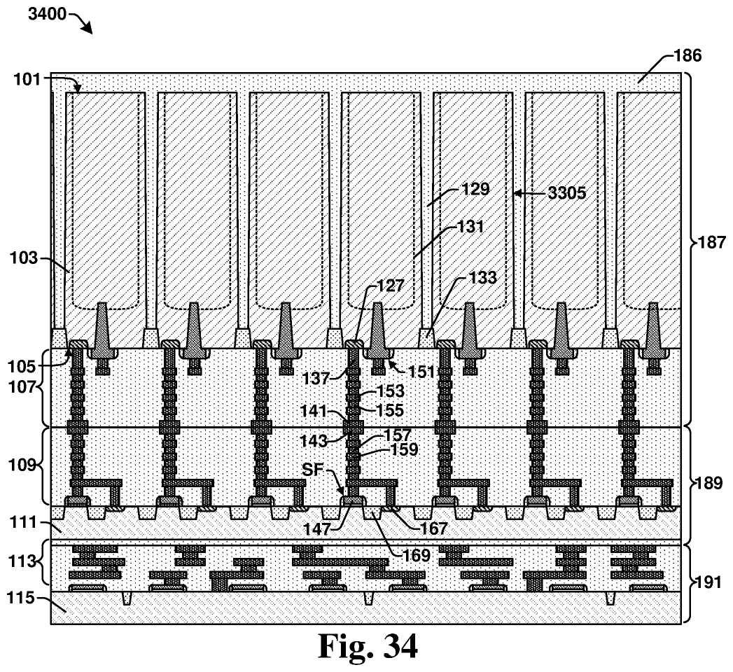

As shown by the cross-sectional view 3200 of FIG. 32, after bonding the semiconductor body 103 may be thinned from the back side 101. Thinning the semiconductor body 103 allows light to pass more easily to the photodiodes 131. The semiconductor body 103 may be thinned by etching, mechanical grinding, CMP, the like, or any other suitable process. In some embodiments, the semiconductor body 103 is thinned to about 5 μm or less. In some embodiments, the semiconductor body 103 is thinned to about 3 μm or less.

As shown by the cross-sectional view 3300 of FIG. 33, a mask 3301 may be formed and used to etch trenches 3303 in the semiconductor body 103. The trenches 3303 form a grid with segments between adjacent photodiodes 131. The trenches 3303 have internal sidewalls 3305 that will define an isolation structure. The trenches 3303 have a high aspect ratio. In some embodiments, the trenches 3303 have an aspect ratio of 15:1 or greater. In some embodiments, the trenches 3303 have an aspect ratio of 20:1 or greater. In some embodiments, the trenches 3303 have an aspect ratio of 25:1 or greater.

The trenches 3303 are formed by etching. In some embodiments, the etching is a multistep etch process in which the trenches are formed in increments. Forming an increment may include etching to a first depth followed by deposition of a protective layer on the internal sidewalls 3305. The protective layer may be, for example, an oxide or a carbide. Etching for the next increment breaks through the protective layer at the bottoms of the trenches. The protective layers reduce lateral etching and trench widening in the upper increments as the lower increments are being formed.

In some embodiments, the etching stops on the STI structures 133, which may have the same grid pattern as the trenches 3303. In some other embodiments, the etching stops on an etch stop layer (not shown) disposed on the front side 105. In some other embodiments, the etching stops on a wire or pad in the first metal interconnect structure 107. These structures provide full isolation between adjacent photodiodes 131. Alternatively, the trenches 3303 stop short of the front side 105 and provide only partial isolation between adjacent photodiodes 131. In the process of this example, a back side DTI structure is formed. Alternatively, a front side DTI structure may be formed.

Continuing with the present example, the trenches 3303 may be filled as shown by the cross-sectional view 3400 of FIG. 34 to provide the DTI structure 129. In some embodiment, the trenches 3303 are filled with dielectric. In other embodiments, the trenches 3303 are lined with dielectric and then filled with conductive material to provide a conductive core. The conductive core may be grounded or may be coupled to a biasing voltage source.

The DTI structure 129 may comprise one or more dielectric layers. As these layers are deposited in the trenches 3303, they also deposit on the back side 101 where they form the dielectric 186. According, the layers of dielectric that make up the DTI structure 129 within the trenches 3303 may be continuous with layers that make up the dielectric 186 on the back side 101. Some of these layers may be thicker on the back side 101 depending on the condition the deposition processes with which they are formed.

In some embodiments, the trenches 3303 are lined with a high-k dielectric layer. The high-k dielectric passivates defects by forming an electric field that accumulates holes along the internal sidewalls 3305, thereby passivating charge carriers (e.g., electrons). The high-κ dielectric layer may be or comprise, for example, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂—Al₂O₃), zirconium oxide (ZrO₂), tantalum oxide (Ta₂O₅), aluminum oxide (Al₂O₃), yttrium oxide (Y₂O₃), lanthanum oxide (La₂O₃), strontium titanium oxide (SrTiO₃), or the like and may have a thickness in the range from 5 to 50 Angstroms, for example. The high-κ dielectric layer may be deposited by ALD, CVD, PVD, the like, or any suitable process.

After lining, the trenches 3303 may be filled with an oxide such as silicon dioxide (SiO₂), tantalum pentoxide (Ta₂O₅), or the like. The fill may be deposited by ALD, CVD, PVD, the like, or any suitable process. In some embodiments, the dielectric 186 includes at least a layer of tantalum pentoxide or the like. Tantalum pentoxide has a refractive index between that of silicon (Si) and that of silicon dioxide. According, a layer of tantalum pentoxide can reduce reflections. Optionally, the dielectric 186 is planarized. Planarization may be by CMP, the like, or any other suitable process. Planarization provides a level surface on which to build the subsequent structure.

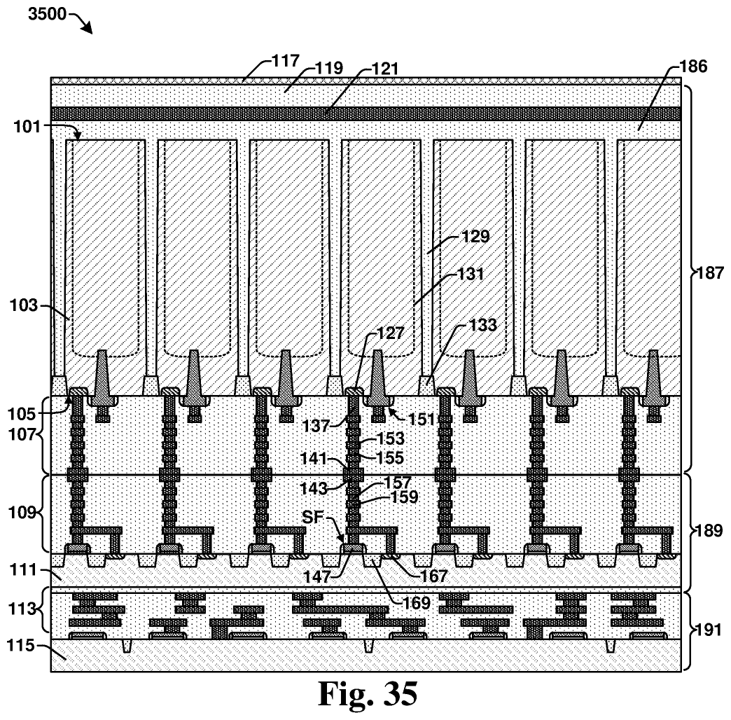

As shown by the cross-sectional view 3500 of FIG. 35, a composite grid stack is formed over the dielectric 186. The composite grid stack includes the metal layer 121, the dielectric layer 119, and the hard mask layer 117. The metal layer 121 may have any suitable composition and thickness. In some embodiments, the metal layer 121 comprises aluminum (Al), copper (Cu), tungsten (W), or the like. In some embodiments, the metal layer 121 comprises tungsten (W) or the like. These materials have good process compatibility and light blocking capability. The dielectric layer 119 may be silicon dioxide (SiO₂), the like, or any other suitable material. The hard mask layer 117 may be silicon nitride (SiN), the like, or any other suitable material. The metal layer 121 may be formed by electroplating, electroless plating, ALD, CVD, PVD, the like, or any other suitable process. The dielectric layer 119 and the hard mask layer 117 may be ALD, CVD, PVD, the like, or any other suitable process. Optionally, the hard mask layer 117 is removed at a later stage of processing.

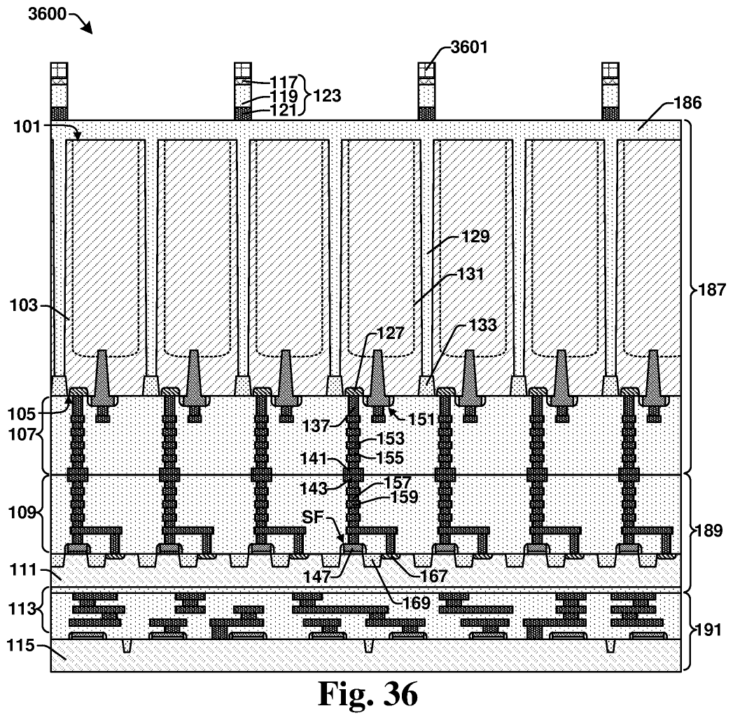

As shown by the cross-sectional view 3600 of FIG. 36, a mask 3601 is formed and used to pattern the composite grid stack to form the composite grid 123. The mask 3601 may be a photoresist patterned by photolithography or e-beam lithography. Patterning using the mask 3601 may comprise dry etching, such as plasma etching or the like. The etch process conditions may be varied as the etch proceeds through the various layers of the composite grid stack.

Further processing forms the encapsulation layer 185, the color filters 183, and the microlenses 181 to provide an image sensor such as the image sensor 100 of FIG. 1. The encapsulation layer 185 is formed over the composite grid 123 and may be a dielectric such as silicon dioxide (SiO₂) or the like. The encapsulation layer 185 may be formed by ALD, CVD, the like, or any other suitable process. The color filters 183 may be formed in openings within the composite grid 123. The color filters 183 may include red, green, and blue color filters. Other color combinations, such as cyan, yellow, and magenta, may be used instead. The color filters 183 may be in a Bayer pattern or some other pattern.

The color filters 183 may comprise polymers formed from polymer resins containing a pigment or dye. The polymer may be, for example, polymethyl-methacrylate (PMMA), poly (glycidyl methacrylate) (PGMS), or the like. The microlenses 181 may be a high transmittance, acrylic polymer, the like or any other suitable material. The microlenses 181 may be formed by depositing and then shaping a microlens layer. In some embodiments, a microlens layer is applied in a liquid state by spin coating or the like. Spin coating can produce a highly uniform microlens layer. Alternatively, the microlens layer may be formed by a deposition technique such as CVD, PVD, the like, or some other suitable process. The microlens layer may be patterned using photolithography. After patterning, the microlens layer may be reflowed to form the curved surfaces of the microlenses 181. After reflowing, the microlens layer may be cured. Curing may be accomplished by UV treatment, the like, or in some other suitable way.

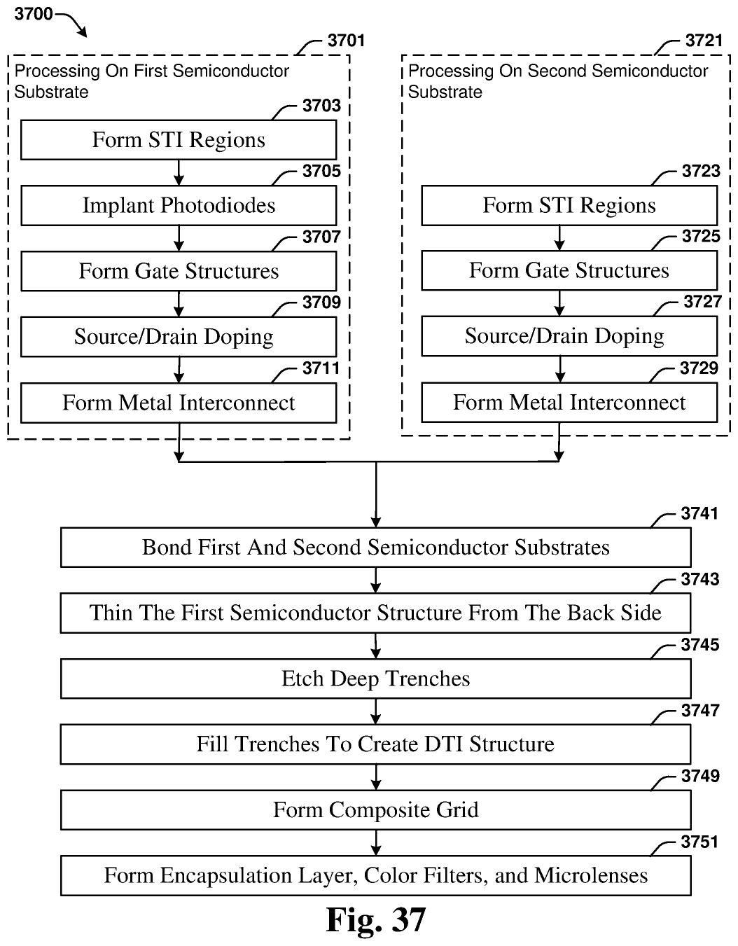

FIG. 37 provides a flow diagram for a process 3700 of forming an image sensing device according to some embodiments. While the process 3700 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The process 3700 begins with a group of acts 3701 which are performed on a first semiconductor substrate with a group of acts 3721 which are performed on a second semiconductor substrate. The acts 3701 may be performed before, after, or simultaneously with the group of acts 3721.

Act 3703 is forming STI structures on the first semiconductor substrate. The cross-sectional view 1600 of FIG. 16 provides an example. These STI structures may be used to land trenches for a back side DTI structure. As previously noted, the trenches for a back side DTI structure could alternatively be landed on a contact etch stop layer or on a wire in a metallization layer. Also, the trenches might simply stop short of the front side, or a front side DTI structure may be formed instead of a back side DTI structure.

Act 3705 is implanting dopants to form photodiodes. The cross-sectional view 1700 of FIG. 17 provides an example. Forming the photodiodes may include a plurality of dopant implantations some of which may be carried out earlier or later in the sequence of acts 3701. For example, photodiode formation may begin with a deep n-well implant made using high energy dopant ions and without a mask.

Act 3707 is forming gate structures on the front side. These may include transfer gates or the like. The cross-sectional views 1800-2100 of FIGS. 18-21 provide an example. Act 3709 is source/drain region doping. This doping forms floating diffusion regions. The cross-sectional view 2200 of FIG. 22 provides an example. Act 3711 is back-end-of-line (BEOL) processing, which forms a metal interconnect structure over a front side of the first semiconductor substrate. The cross-sectional view 2300 of FIG. 23 provides an example.

Act 3723 is forming STI regions in the second semiconductor substrate. These STI regions may define active device areas, for example, the first active device area 405 and the second active device area 407 illustrated in FIG. 4. FIG. 24 provides a cross-sectional view 2400 illustrating the formation of the STI regions in the second semiconductor substrate. Act 3725 is forming gate structures on the second semiconductor substrate. These include source followers, select gate transistors, reset transistors, dual conversion gate transistors, or the like. The source followers, the select gate transistors, the reset transistors, the dual conversion gate transistors correspond in number to the floating diffusion regions formed in act 3709.

The cross-sectional views 2500-2700 of FIGS. 25-27 provide an example. Act 3727 is source/drain doping. The cross-sectional view 2800 of FIG. 28 provides an example. Act 3729 is back-end-of-line (BEOL) processing which forms the second metal interconnect structure on the second semiconductor substrate. The cross-sectional view 2900 of FIG. 29 provides an example.

Act 3741 is aligning the first and second semiconductor substrates and bonding them together. The second semiconductor substrate may also be bonded to a third semiconductor substrate either before or after bonding to the first semiconductor substrate. The cross-sectional view 3000 of FIG. 30 provides an example. The first and second semiconductor substrates may be aligned so that the floating diffusion regions are directly opposite the gate electrodes of corresponding source followers as in the image sensor 100 of FIG. 1, they may be aligned so that the floating diffusion regions are directly opposite the source regions of corresponding dual conversion gate transistors as in the image corresponding 1400 of FIG. 14, or they may be aligned so that the floating diffusion regions are directly opposite intermediate locations as in the image corresponding 1500 of FIG. 15.

Act 3743 is thinning the first semiconductor substrate from the back side. The cross-sectional view 3100 of FIG. 31 provides an example. Act 3745 is etching deep trenches in the back side. The cross-sectional view 3200 of FIG. 32 provides an example. Act 3747 is filling the trenches to provide a DTI structure. The cross-sectional view 3300 of FIG. 33 provides an example. The trenches may be lined with one or more layers of high-k dielectric and then filled with another dielectric. Alternatively, the trenches may be filled with a conductive material after being lined with dielectric. Another alternative is to form a front side DTI structure rather than a back side DTI structure.

Act 3749 is forming a composite grid on the back side. The cross-sectional views 3400-3500 of FIGS. 34-35 provide an example. Act 3751 is additional processing that completes the formation of an image sensing device. The may include forming an encapsulation layer over the composite grid, forming color filters, and forming microlenses. The image sensors 100, 1400, and 1500 of FIGS. 1, 14, and 15 provide examples of the resulting structure.

Some aspects of the present disclosure relate to an image sensor that includes a first semiconductor substrate, a first metal interconnect structure formed on the first semiconductor substrate, a second semiconductor substrate, and a second metal interconnect structure formed on the second semiconductor substrate. The first semiconductor substrate is bound to the second semiconductor substrate via a binding between the first metal interconnect structure and the second metal interconnect structure. The image sensor includes an array of photodetectors each comprising a photosensitive area, a floating diffusion region, a transfer gate, a source follower (SF), a select gate transistor, a dual conversion gain (DCG) transistor, and a reset transistor. The photosensitive area and the floating diffusion region are within the first semiconductor substrate. The transfer gate is on the first semiconductor substrate. The SF, the select gate transistor, the DCG transistor, and the reset transistor are on the second semiconductor substrate. There is a one-to-one correspondence between the floating diffusion regions on the first semiconductor substrate and the SFs on the second semiconductor substrate.

In some embodiments the DCG transistor is connected in series with the reset transistor and the floating diffusion region is coupled to a source side of the DCG transistor. In some embodiments, a first contact plug abuts a source side of the DCG transistor, a second contact plug that abuts a gate electrode of the SF, a horizontal wire extends between the first contact plug and the second contact plug, and a straight vertical column of metal extends between the horizontal wire and the floating diffusion region.

In some embodiments, a distance between the DCG transistor and the SF equals a width of an isolation structure between the DCG transistor and the SF. In some embodiments, the distance between the DCG transistor and the SF equals a distance between a source region of the DCG transistor and a gate electrode of the SF. In some embodiments, the DCG transistor and the SF have parallel orientations. In some embodiments, the DCG transistor and the SF have perpendicular orientations.

In some embodiments, the image sensor further includes an array of lenses each of which is positioned to focus light on four of the photosensitive areas. In some embodiments, two of the photosensitive areas are in image sensing pixels and two are in phase detection autofocus pixels.

Some aspects of the present disclosure relate to an image sensor that includes a first semiconductor substrate, a first metal interconnect structure formed on the first semiconductor substrate, a second semiconductor substrate, and a second metal interconnect structure formed on the second semiconductor substrate. The first semiconductor substrate is bound to the second semiconductor substrate via a binding between the first metal interconnect structure and the second metal interconnect structure. The image sensor includes an array of photodetectors each comprising a photosensitive area, a floating diffusion region, a transfer gate, a source follower (SF), a select gate transistor, a dual conversion gain (DCG) transistor, and a reset transistor. The photosensitive area and the floating diffusion region are within the first semiconductor substrate. The transfer gate is on the first semiconductor substrate. The SF, the select gate transistor, the DCG transistor, and the reset transistor are on the second semiconductor substrate. A wiring structure couples the floating diffusion region to a gate electrode of the SF and to a source region of the DCG transistor or of the reset transistor. An isolation structure forms a grid within the first semiconductor substrate. The photosensitive area and the floating diffusion region are contained within a cell of the grid. The gate electrode, the source region, and the wiring structure are contained within a vertical extension of the cell.

In some embodiments, the reset transistor is connected in series with the DCG transistor and the wiring structure couples the floating diffusion region to the source region of the DCG transistor. In some embodiments, the wiring structure comprises a first wire in the second metal interconnect structure, the first wire couples the source region of the DCG transistor to the gate electrode of the source follower, and the floating diffusion region is directly opposite the first wire so as to be horizontally aligned with the first wire. In some embodiments, the wiring structure comprises a straight vertical column of metal connecting the floating diffusion region to the first wire.

In some embodiments, the floating diffusion region is in a corner of the cell. In some embodiments, the isolation structure extends from the first side to the second side. In some embodiments, wherein the floating diffusion region is on a source side of the transfer gate and a drain side of the transfer gate is wider than the source side of the transfer gate.

Some aspects of the present disclosure relate to method of making an image sensor. The method includes providing a first semiconductor substrate and a second semiconductor substrate, forming a grid isolation structure in the first semiconductor substrate so as to define cells, which are portions of the first semiconductor substrate that are laterally surrounded by segments of the grid isolation structure, forming floating diffusion regions within the cells, forming a first metal interconnect structure on the first semiconductor substrate, forming source followers (SFs), select gate transistors, dual conversion gain transistors (DCG) transistors, and reset transistors on the second semiconductor substrate, wherein there is one SF for each floating diffusion region, forming a second metal interconnect structure on the second semiconductor substrate; and coupling the first metal interconnect structure to the second metal interconnect structure so that the floating diffusion regions are coupled to respective SFs.

In some embodiments, the reset transistors and the DCG transistors are connected in series and coupling the first metal interconnect structure to the second metal interconnect structure provides wiring that couples the floating diffusion regions directly to corresponding DCG transistors. In some embodiments, each instance of the wiring that couples the floating diffusion regions directly to the corresponding DCG transistors contains only a single branch. In some embodiments, the method further includes providing a third semiconductor substrate, forming an integrated circuit on the third semiconductor substrate, and bonding the third semiconductor to the second semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a first semiconductor substrate having a first side and a second side;
a first metal interconnect structure comprising a plurality of metallization layers over the first side;
a second semiconductor substrate;
a second metal interconnect structure comprising a plurality of metallization layers over the second semiconductor substrate, wherein the first semiconductor substrate is bound to the second semiconductor substrate via a binding between the first metal interconnect structure and the second metal interconnect structure; and
an array of photodetectors each comprising a photosensitive area, a floating diffusion region, a transfer gate, a source follower (SF), a select gate transistor, a dual conversion gain (DCG) transistor, and a reset transistor, wherein the photosensitive area and the floating diffusion region are within the first semiconductor substrate, the transfer gate is on the first semiconductor substrate, and the SF, the select gate transistor, the DCG transistor, and the reset transistor are on the second semiconductor substrate;
wherein there is a one-to-one correspondence between the floating diffusion regions on the first semiconductor substrate and the SFs on the second semiconductor substrate.

2. The image sensor of claim 1, wherein the DCG transistor is connected in series with the reset transistor and the floating diffusion region is coupled to a source side of the DCG transistor.

3. The image sensor of claim 2, further comprising:
a first contact plug that abuts the source side of the DCG transistor;
a second contact plug that abuts a gate electrode of the SF;
a horizontal wire that extends between the first contact plug and the second contact plug; and
a straight vertical column of metal extending between the horizontal wire and the floating diffusion region, wherein the straight vertical column comprises first components in the first metal interconnect structure and second components in the second metal interconnect structure.

4. The image sensor of claim 1, wherein a distance between the DCG transistor and the SF equals a width of an isolation structure between the DCG transistor and the SF.

5. The image sensor of claim 4, wherein the distance between the DCG transistor and the SF equals a distance between a source region of the DCG transistor and a gate electrode of the SF.

6. The image sensor of claim 5, wherein the DCG transistor and the SF have parallel orientations.

7. The image sensor of claim 5, wherein the DCG transistor and the SF have perpendicular orientations.

8. The image sensor of claim 1, further comprising an array of lenses, wherein the lenses are positioned to focus light on groups of four photosensitive areas.

9. The image sensor of claim 8, wherein two of the four photosensitive areas are in image sensing pixels and two are in phase detection autofocus pixels.

10. An image sensor, comprising:
a first semiconductor substrate having a first side and a second side;
a first metal interconnect structure comprising a plurality of metallization layers over the first side;
a second semiconductor substrate;
a second metal interconnect structure comprising a plurality of metallization layers over the second semiconductor substrate, wherein the first semiconductor substrate is bound to the second semiconductor substrate via a binding between the first metal interconnect structure and the second metal interconnect structure;
a photodetector comprising a photosensitive area, a floating diffusion region, a transfer gate, a source follower (SF), a select gate transistor, a dual conversion gain (DCG) transistor, and a reset transistor, wherein the photosensitive area and the floating diffusion region are within the first semiconductor substrate, the transfer gate is on the first semiconductor substrate, and the SF, the select gate transistor, the DCG transistor, and the reset transistor are on the second semiconductor substrate;
a wiring structure with components in the first metal interconnect structure and the second metal interconnect structure, wherein the wiring structure couples the floating diffusion region to a gate electrode of the SF and to a source region of the DCG transistor or of the reset transistor; and
an isolation structure forming a grid within the first semiconductor substrate, wherein the photosensitive area and the floating diffusion region are contained within a cell of the grid and the gate electrode, the source region, and the wiring structure is contained within a vertical extension of the cell.

11. The image sensor of claim 10, wherein the reset transistor is connected in series with the DCG transistor and the wiring structure couples the floating diffusion region to the source region of the DCG transistor.

12. The image sensor of claim 11, wherein:
the wiring structure comprises a first wire in the second metal interconnect structure;
the first wire couples the source region of the DCG transistor to the gate electrode of the source follower; and
the floating diffusion region is directly opposite the first wire so as to be horizontally aligned with the first wire.

13. The image sensor of claim 12, wherein the wiring structure comprises a straight vertical column of metal connecting the floating diffusion region to the first wire.

14. The image sensor of claim 10, wherein the floating diffusion region is in a corner of the cell.

15. The image sensor of claim 10, wherein the isolation structure extends from the first side to the second side.

16. The image sensor of claim 10, wherein the floating diffusion region is on a source side of the transfer gate and a drain side of the transfer gate is wider than the source side of the transfer gate.

17. A method of making an image sensor, the method comprising:
providing a first semiconductor substrate and a second semiconductor substrate;
forming a grid isolation structure in the first semiconductor substrate so as to define cells, wherein the cells are portions of the first semiconductor substrate that are laterally surrounded by segments of the grid isolation structure;
forming floating diffusion regions within the cells;
forming a first metal interconnect structure on the first semiconductor substrate;
forming source followers (SFs), select gate transistors, dual conversion gain transistors (DCG) transistors, and reset transistors on the second semiconductor substrate, wherein there is one SF for each floating diffusion region;
forming a second metal interconnect structure on the second semiconductor substrate; and
coupling the first metal interconnect structure to the second metal interconnect structure so that the floating diffusion regions are coupled to respective SFs.

18. The method of claim 17, wherein:
the reset transistors and the DCG transistors are connected in series; and
coupling the first metal interconnect structure to the second metal interconnect structure provides wiring that couples the floating diffusion regions directly to corresponding DCG transistors.

19. The method of claim 18, wherein each instance of the wiring that couples the floating diffusion regions directly to the corresponding DCG transistors contains only a single branch.

20. The method of claim 17, further comprising providing a third semiconductor substrate, forming an integrated circuit on the third semiconductor substrate, and bonding the third semiconductor to the second semiconductor substrate.
